(19) United States
(12) Patent Application Publication
(10) Pub. No.: US 2012/0306040 A1
(43) Pub. Date: Dec. 6, 2012

(54) INSULATING METAL SUBSTRATE AND SEMICONDUCTOR DEVICE

(75) Inventor: Shigenori Yuya, Ashigara-kami-gun (JP)

(73) Assignee: FUJIFILM CORPORATION, Minato-ku, Tokyo (JP)

(21) Appl. No.: 13/576,340

(22) PCT Filed: Jan. 26, 2011
(86) PCT No.: PCT/JP2011/000405

§ 371 Date: Jul. 31, 2012

(30) Foreign Application Priority Data
Feb. 1, 2010 (JP) 2010-020313

(51) Int. Cl. B32B 15/01; B32B 5/18; B32B 15/18; H01L 31/042; B32B 15/20

(52) U.S. Cl. 257/443; 428/632; 428/613; 257/E27.124

(57) ABSTRACT

An insulating metal substrate is used for a semiconductor device such as a solar cell. The substrate includes a metal base made of steel, iron-based alloy steel or titanium, an aluminum layer and an insulating layer obtained by anodizing aluminum. An alloy layer primarily made of an alloy of a composition expressed by Al₃X (where X is at least one kind of element selected from Fe, Cr, and Ti) exists in an interface between the metal base and the aluminum layer, and has a thickness of 0.01 to 10 micrometers. The aluminum layer has a thickness of 1 micrometer or more and equal to or less than a thickness of the metal base.

### TECHNICAL FIELD

The present invention relates to an insulating metal substrate having excellent insulation characteristics, and a semiconductor device such as a solar cell which uses this substrate.

### BACKGROUND ART

Silicon solar cells using bulk monocrystalline silicon or polycrystalline silicon or thin-film amorphous silicon have conventionally been mainly employed, but compound semiconductor solar cells which do not depend on silicon are recently under research and development.

Known compound semiconductor-based solar cells include those made from III-VI compounds such as GaAs, II-VI compounds such as CdTe, and compounds such as CIS (Cu—In—Se) and CIGS (Cu—In—Ga—Se). CIS and CIGS are reported to have high optical absorbance and high photoelectric conversion efficiency.

At present, glass substrates are mainly used for solar cells, but use of flexible metallic substrates is under investigation.

There is a possibility that compound thin-film solar cells using metallic substrates can be applied to a wide variety of applications compared to ordinary ones using glass substrates, based on characteristics such as the light weight and flexibility of the substrates. In addition, from the viewpoint that the metallic substrates can withstand high-temperature processes, the light absorbing layer can be formed at high temperatures to hold promise for higher efficiency of solar cells together with improved photoelectric conversion properties.

Solar cells (Solar cells module) are connected in series on a single substrate and integrated into a solar cell module, whereby the efficiency of the module can be improved. In cases where a metallic substrate is used in this process, it is necessary to form an insulation layer on the metallic substrate and provide a semiconductor circuit layer for photoelectric conversion.

For example, JP 2001-339081 A describes that iron materials such as stainless steels are used for the solar cell substrate and an insulation layer is formed by coating the substrate with silicon oxide or aluminum oxide by a vapor-phase deposition technique such as CVD or a liquid-phase deposition technique such as the sol-gel method.

However, these techniques tend to cause pinholes and cracks, and have essential problems in consistently preparing a large-area thin-film insulation layer.

On the other hand, in the case of aluminum (Al), an insulation film having no pinholes and exhibiting good adhesion is obtained by forming an anodic oxide (anodized aluminum oxide (AAO)) film on its surface.

Therefore, as described in JP 2000-49372 A, solar cell modules using a substrate obtained by forming an anodized film serving as the insulation layer on a surface of an aluminum substrate are under active research.

As described by Masashi Kayashima and Masakatsu Mushiro in Tokyo Metropolitan Industrial Technology Research Institute, Research Report, No. 3, December, 2000, p. 21 (“Non-Patent Literature 1” hereinafter), cracks are known to be formed in the anodized film formed at the aluminum surface by heating to a temperature of 120 deg C. or more.

However, in order to achieve high-quality photoelectric conversion efficiency, the light absorbing layer made of a compound semiconductor and particularly of a CIGS compound semiconductor is to be deposited at a higher film deposition temperature, and the film deposition temperature is typically at least 500 deg C.

Cracking or delamination of the anodized film may occur during the formation of the light absorbing layer or upon cooling after film deposition when a substrate having an anodized aluminum film serving as the insulation layer is used for the substrate of the solar cell substrate having the light absorbing layer made of a compound semiconductor.

Once cracking occurs, the insulation properties are deteriorated and particularly the leakage current is increased, leading to unsatisfactory photoelectric conversion efficiency. Breakdown may also occur.

What is more, aluminum softens at around 200 deg C. and therefore an aluminum substrate having experienced a temperature equal to or higher than this value has extremely low strength and easily undergoes permanent deformation (plastic deformation) such as creep deformation or buckling deformation.

Therefore, handling of solar cells using aluminum substrates is to be strictly restricted also during the manufacture thereof. This makes it difficult for such solar cells that use aluminum substrates to be applied to outdoor solar cell units.

In contrast, JP 2009-132996 A discloses a heat-resistant insulating substrate wherein a layer made from an anodizable metal such as aluminum is provided as an intermediate layer on the front surface of a metal substrate such as stainless steel, copper, aluminum, titanium, iron or iron alloy, and a film formed by anodizing this intermediate layer is used as the insulation layer. By such a structure, it is possible to obtain an insulating metal substrate which is heat resistant to a certain degree.

However, as stated in S. K. Mannan, V. Seetharaman and V. S. Raghunathan, Materials Science and Engineering, Vol. 60 (1983), p. 79-86, it is also known that a brittle inter metallic compound (IMC) is produced at the interface between the Al layer and the steel base when the metal material resulting from the formation of an Al layer on a steel base is heated to about 500 deg C., and due to this intermetallic compound, the interface strength between the Al layer and the steel base decreases, and the layers end up delaminating.

### CITATION LIST

### Patent Literature

[PTL 1]
JP 2001-339081 A
[PTL 2]
JP 2000-49372 A
[PTL 3]
JP 2009-132996 A

### Non Patent Literature

[NPL 1]
Masashi Kayashima and Masakatsu Mushiro in Tokyo Metropolitan Industrial Technology Research Institute, Research Report, No. 3, December, 2000, p. 21
[NPL 2]
S. K. Mannan, V. Seetharaman and V. S. Raghunathan, Materials Science and Engineering, Vol 60 (1983) p 79-86

### SUMMARY OF INVENTION

### Technical Problem

As described above, when one of the compound semiconductors currently being studied is used as the light absorbing layer, the deposition temperature of the light absorbing layer must be high in order to obtain high photoelectric conversion efficiency. This deposition temperature is generally at least 500 deg C., and higher temperatures are more advantageous.

For this reason, in substrates in which an Al layer is laminated on a steel substrate, there is the problem that interface strength decreases due to the intermetallic compound formed at the interface between the Al layer and the steel base, and at present, there are no satisfactory metal substrates with an insulation layer for use in solar cells.

The objective of the present invention is to provide an insulating metal substrate which has good insulation characteristics and mechanical strength and is flexible, even after going through high-temperature manufacturing processes of semiconductor circuits, such as, for example, deposition of the light absorbing layer in a thin-film solar cell having a light absorbing layer made from a compound semiconductor. In particular, the objective of the present invention is to provide, in a large-area semiconductor device such as a solar cell, a flexible insulating metal substrate which can be manufactured by a roll-to-roll system, and a semiconductor device such as a solar cell module which uses this insulating metal substrate.

### Solution to Problem

To achieve the above objective, the present invention provides an insulating metal substrate including: a metal base made of steel, iron-based alloy steel or titanium; an aluminum layer provided on at least one surface of said metal base; an insulation layer formed by anodizing a front surface of said aluminum layer; and an alloy layer primarily made of an alloy of a composition expressed by Al₃X (where X is at least one kind of element selected from Fe, Cr, and Ti) and existing in an interface between said metal base and said aluminum layer, wherein said alloy layer has a thickness of 0.01 to 10 micrometers, and wherein said aluminum layer has a thickness of 1 micrometer or more and equal to or less than a thickness of said metal base.

In the insulating metal substrate according to the present invention, it is preferable that the insulation layer is an anodized film of aluminum having a porous structure. Further, it is preferable that the aluminum layer is provided on said at least one surface of said metal base by pressure bonding an aluminum sheet on said at least one surface of said metal base. Further, it is preferable that the metal base has a thickness of 10 to 1000 micrometers. Furthermore, it is preferable that the insulation layer has a thickness of 0.5 to 50 micrometers

According to another aspect of the present invention, there is provides a semiconductor device including: the insulating metal substrate of the present invention; and semiconductor elements arranged in an array on a front surface of said insulating metal substrate.

In the insulating metal substrate according to the present invention, it is preferable that the semiconductor elements are photoelectric conversion elements connected in series. Further, it is preferable that the each of said photoelectric conversion elements have a light absorbing layer comprising a compound semiconductor having a chalcopyrite-type crystalline structure. Further, it is preferable that the each of said photoelectric conversion elements have a bottom electrode made of molybdenum, and said compound semiconductor comprises at least one compound semiconductor made of a group Ib element, group IIIb element and group VIb element. Furthermore, it is preferable that the group Ib element comprises copper and/or silver, the group IIIb element comprises at least one element selected from the group consisting aluminum, gallium and indium, and said group VIb element comprises at least one element selected from the group consisting of sulfur, selenium and tellurium.

### Advantageous Effects of Invention

The insulating metal substrate and semiconductor device of the present invention having the above structure has an alloy layer (inter-metallic layer) of thickness 0.01 to 10 micrometers between the metal base and the Al layer, after the manufacture of a solar cell module, for example, has been completed by going through manufacturing processes including deposition of the compound semiconductor-based light absorbing layer such as CIGS at a deposition temperature of at least 500 deg C.

For this reason, between the metal base and the Al layer, there is no delamination or cracking of the Al layer and no delamination or cracking of the insulation layer caused thereby.

As a result, the insulating metal substrate of the present invention has good insulation characteristics and mechanical strength and is flexible. Also, the semiconductor device of the present invention that uses the above insulating metal substrate has suitable characteristics that inhibit performance degradation caused by a reduction in insulation characteristics, or a decrease in mechanical strength caused by a decrease in strength of the substrate.

As described above, the present invention is capable of maintaining high insulation properties and high strength even after being processed at a temperature of 500 deg C. or more. In other words, a manufacturing step at a high temperature of 500 deg C. or more is possible and the light absorbing layer made of a compound semiconductor can be formed at a film deposition temperature of 500 deg C. or more.

The compound semiconductor making up the light absorbing layer should be formed at a high temperature so that photoelectric conversion properties may be improved. Therefore, according to the present invention, a solar cell having a light absorbing layer with improved photoelectric conversion properties can be obtained by film deposition at a temperature of 500 deg C. or more.

Even in cases where the process contains a manufacturing step at a high temperature of 500 deg C. or more, sufficient strength of the substrate can be ensured, thus making it possible to eliminate limitations on handling during manufacturing.

### BRIEF DESCRIPTION OF DRAWINGS

FIG. 1 is a view schematically illustrating an example of the solar cell which uses the insulating metal substrate of the present invention.

FIG. 2 is a view schematically illustrating an example of the insulating metal substrate before the alloy layer is generated.

FIG. 3A schematically illustrates the heat treatment conditions that result in an intermetallic compound thickness of 10 micrometers in the metal material in which an Al layer is provided on a base.

FIG. 3B schematically illustrates the heat treatment conditions that result in an intermetallic compound thickness of 5 micrometers in the metal material in which an Al layer is provided on a base.

FIG. 4A is a chart that was output by image processing of a photograph of the cross-section of the substrate.

FIG. 4B is a chart that was output by image processing of a photograph of the cross-section of the substrate.

FIG. 4C is a chart that was output by image processing of a photograph of the cross-section of the substrate.

FIG. 4D is a chart that was output by image processing of a photograph of the cross-section of the substrate.

FIG. 5E is a chart that was output by image processing of a photograph of the cross-section of the substrate.

### DESCRIPTION OF EMBODIMENTS

The insulating metal substrate and the semiconductor device of the present invention are described in detail below with reference to preferred embodiments shown in the accompanying drawings.

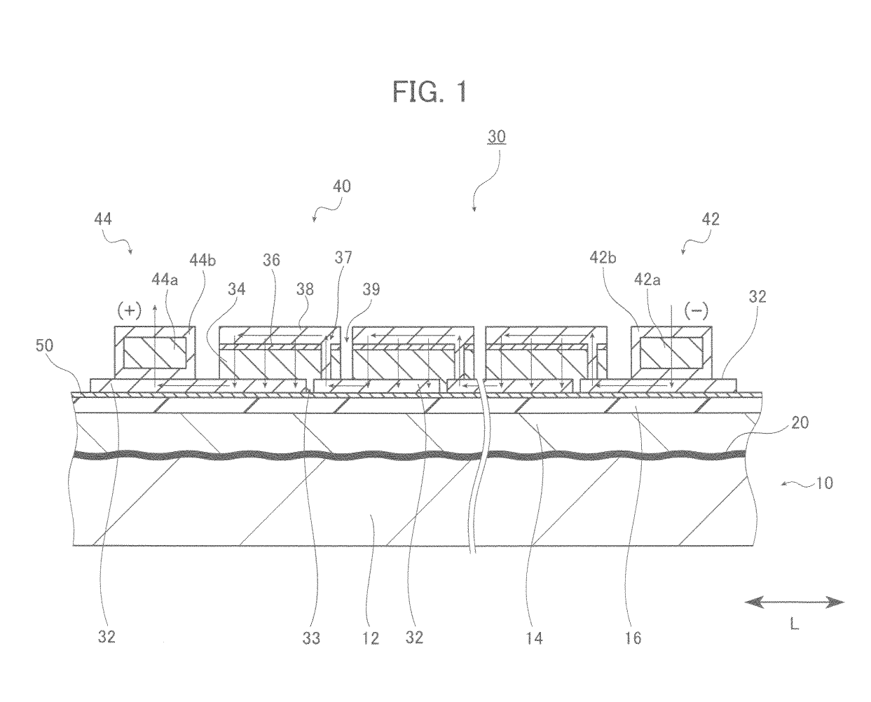

FIG. 1 is a cross-sectional diagram schematically showing an example in which the semiconductor device of the present invention, which uses the insulating metal substrate of the present invention, is utilized in a solar cell module.

The solar cell module 30 (called “solar cell 30” hereinafter) shown in FIG. 1 is a module-type solar cell in which a plurality of thin-film solar cells 40, comprising lower electrodes 32, a light absorbing layer 34, a buffer layer 36 and upper electrodes 38, are joined in series on an insulating metal substrate 10. Also, on top of the lower electrodes 32 on the two ends in the direction of array of the thin-film solar cells 40, a first conductive member 42 and a second conductive member 44 are formed, for collecting the electromotive force generated by the thin-film solar cells 40 which are connected in series.

In the solar cell 30, the insulating substrate 10 (called “substrate 10” hereinafter) is the insulating substrate of the present invention, constructed from a metal base 12, an Al (aluminum) layer 14 and an insulation layer 16. The insulation layer 16 is made of an anodized aluminum film obtained by anodizing the surface of the Al layer 14.

Also, in the substrate 10 of the present invention, an alloy layer 20 is generated between the metal base 12 and the Al layer 14.

In the substrate 10 (solar cell 30 (semiconductor device)) of the present invention, the thickness of the Al layer 14 is 1 micrometer or more and equal to or less than the thickness of the metal base 12, and the thickness of the alloy layer 20 is 0.01 to 10 micrometers. This point will be described in detail below.

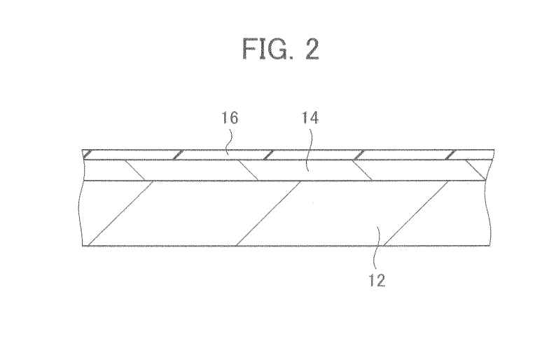

FIG. 2 schematically shows a cross-sectional diagram showing an example of the substrate 10 before the alloy layer 20 is generated.

The metal base 12 (called “base 12” hereinafter) serves as the foundation of the substrate 10 of the present invention, and is a flat metal sheet, for example.

Various metal materials may be used as the material of the base 12 without particular restriction, but preferred examples are steel, iron-based alloy steel and titanium (including titanium alloys). Note that iron-based alloy steel means alloy steel in which iron is the primary constituent element.

Specifically, the material of the base 12 may be appropriately selected based on the results of stress calculations from materials characteristics and the overall layer structure of the semiconductor device and the insulating substrate part. Considering control of linear expansion coefficient and so forth, preferred steel bases include austenitic stainless steel (linear expansion coefficient: 17×10⁻⁶/deg C), carbon steel (10.8×10⁻⁶/deg C), ferritic stainless steel (10.5×10⁻⁶/deg C), 42 Invar alloy or Kovar alloy (5×10⁻⁶/deg C), 36 invar alloy (<1×10⁻⁶/deg C) and so forth. Also, as titanium material, titanium (linear expansion coefficient: 9.2×10⁻⁶/deg C) may be used, but it is not limited to pure titanium, and the wrought alloys Ti-6Al-4V and Ti-15V-3Cr-3Al-3Sn may be used because they have substantially the same linear expansion coefficient as titanium.

The thickness of the base 12 is not particularly limited, and may be appropriately selected in accordance with the handling characteristics (strength and flexibility) required in the manufacturing process and during the operation of the solar cell 30 (semiconductor device).

Considering this point, the thickness of the base 12 is preferably 10 to 1000 micrometers.

Also, the strength of the substrate 12 is not particularly limited, but it must have strength to the extent that it has elastic limit stress such that it does not plastically deform. The 0.2% proof stress of the base 12, although dependent upon the degree of machining and thermal refining of the base 12, is preferably 250 to 900 MPa at room temperature. Note that if there are high-temperature processes in the manufacture of the solar cell 30, the temperature dependence of the 0.2% proof stress is also important. As described above, steel and titanium maintain proof stress of about 70% at a temperature of 500 deg C. This ensures elastic limit stress at which no plastic deformation occurs even in cases where the substrate 10 has undergone a thermal history of 500 deg C., which is the film deposition temperature of the light absorbing layer.

0.2% proof stress and its temperature dependence are described in “Steel Material Handbook” edited by the Japan Institute of Metals and the Iron and Steel Institute of Japan and published by Maruzen Co., Ltd.

Note that yield stress may also be used as an index of the strength of the base 12.

The Young's moduli of aluminum and steel and their temperature dependencies needed for stress calculation are described in “Stainless Steel Handbook (3^{rd} edition)” edited by the Japan Stainless Steel Association and published by Nikkan Kogyo Shimbun, Ltd.

The Al layer 14 is formed on the front surface of the base 12.

Note that in the present invention, the alloy layer 20 is generated at the interface between the two. This alloy layer 20 will be described in detail below.

The Al layer 14 is mainly an aluminum-based layer, and various materials such as aluminum and aluminum alloys may be used. More specifically, aluminum with a purity of 99 mass % or more which contains few impurities is preferably used. For example, aluminum with a purity of 99.99 mass %, aluminum with a purity of 99.96 mass %, aluminum with a purity of 99.9 mass %, aluminum with a purity of 99.85 mass %, aluminum with a purity of 99.7 mass %, and aluminum with a purity of 99.5 mass % are preferred.

Aluminum for industrial use may also be used even if it is not high-purity aluminum. Use of such aluminum for industrial use is advantageous in terms of cost. However, it is important for silicon not to precipitate out in the aluminum from the viewpoint of the insulation properties of the insulation layer 16.

In the substrate 10 of the present invention, the insulation layer 16 made by anodizing aluminum is formed on the front surface of the Al layer 14 formed on the base 12.

As also described in Non-Patent Literature 1, cracks are formed in the anodized aluminum film formed on the aluminum surface by heating to a temperature of 120 deg C. or more.

The cause of cracking in the anodized film formed on the Al layer is thought to be the fact that the linear expansion coefficient (coefficient of linear thermal expansion) of aluminum is larger than that of the anodized film.

That is, the linear expansion coefficient of aluminum is 23×10⁻⁶/deg C. In contrast, the exact value of the linear expansion coefficient of the anodized aluminum film is not known, but the value is estimated to be about 7×10⁻⁶/deg C., which is close to that of aluminum oxide (alpha alumina). In view of this point, it is believed that the anodized film cannot withstand the stress due to a large difference in the linear expansion coefficient of about 16×10⁻⁶/deg C., and therefore cracks are formed in the anodized film on the aluminum material as described above.

Therefore, in a solar cell using a substrate having an insulation layer obtained by anodizing the surface of an aluminum material, heating may cause cracking or delamination of the insulation layer during the formation of a light absorbing layer made of a compound semiconductor which requires a film deposition temperature of 500 deg C. or more, whereupon sufficient insulation properties cannot be obtained.

In contrast, in the present invention, the base 12 governs the strength and the linear expansion coefficient of the overall substrate, and stress caused by the slight difference in thermal expansion between the base 12 and the anodized aluminum film insulation layer 16 is absorbed by interposition of the Al layer 14, which has a lower Young's modulus than the base 12 and insulation layer 16. As a result, cracking of the insulation layer 16, that is, the anodized aluminum film, caused by the difference in thermal expansion coefficient can be inhibited.

Also, although it depends on the degree of mechanical processing and thermal refining, aluminum has a proof stress at room temperature of at least 300 MPa, but the proof stress drops at 500 deg C. to not more than 1/20 that at room temperature. On the other hand, the proof stress at 500 deg C. of steel of titanium maintains a level of about 70% of that at room temperature. Therefore, the base 12 governs the elastic stress limit and thermal expansion of the substrate 10 at high temperatures. In other words, sufficient rigidity of the substrate 10 can be ensured even in an environment of a high temperature of 500 deg C. or more by forming the substrate 10 by combining the Al layer 14 and the base 12. Even in cases where the process includes a manufacturing step at a high temperature of 500 deg C. or more, sufficient rigidity of the substrate can be ensured, thus making it possible to eliminate limitations on handling during manufacturing.

In the present invention, the thickness of the Al layer 14 is 1 micrometer or more and equal to or less than the thickness of the metal base 12, in the situation where it is used in a solar cell 30 (semiconductor device).

Note that the thickness of the Al layer 14 means the average thickness of a cross-section of the base 12 (insulating metal substrate), similar to the thickness of the alloy layer 20 described below.

If the thickness of the Al layer 14 is less than 1 micrometer, a sufficient stress relief effect cannot be obtained. Also, if the Al layer 14 is less than 1 micrometer, the alloy 20 described below may partially come in direct contact with the insulation layer 16 (anodized aluminum film), and this ends up becoming the origin of film destruction of the insulation layer 16.

Conversely, if the Al layer 14 is too thick, residual warpage is large when high temperature is incurred, hindering the subsequent manufacturing processes of the solar cell 30 (semiconductor device). It is also disadvantageous from the standpoint of materials costs of the solar cell 30. Although it varies depending on the high-temperature softening characteristics of aluminum and the Young's modulus of the base 12 which is the main constituent of thermal expansion, residual warpage is small when the thickness of the Al layer 14 is less than or equal to the thickness of the base 12. Also, even when some warpage occurs, it does not hinder subsequent manufacturing processes since bending rigidity of the base 12 itself is low.

The thickness of the Al layer 14 is reduced (aluminum is consumed) by the pretreatment of the aluminum surface, the formation of the insulation layer 16 by anodization, and the formation of the alloy layer 20 at the interface between the Al layer 14 and the base 12 during the deposition of the light absorbing layer 34.

Therefore, it is important for the thickness of the Al layer 14 when formed (to be described later) to be determined while considering the reduction of the thickness due to the foregoing factors, so that the Al layer 14 may remain between the base 12 and the insulation layer 16 at a thickness of at least 1 micrometer in the state where the solar cell 30 has been completed.

The insulation layer 16 is formed on the Al layer 14 (on the opposite side from the base 12). The insulation layer 16 is made of an anodized aluminum film obtained by anodizing the surface of the Al layer 14.

Various types of film obtained by anodizing aluminum may be used for the insulation layer 16, but a porous anodized film obtained from an acidic electrolytic solution to be described later is preferably used. The anodized film is an aluminum oxide film having micropores with a size of several tens of nanometers, which has a low Young's modulus and therefore exhibits high bending resistance and high resistance to cracking caused by the difference in the thermal expansion at high temperatures.

The insulation layer 16 preferably has a thickness of 2 micrometers or more, and more preferably 5 micrometers or more. An excessively thick insulation layer 16 is not preferred because flexibility is reduced and cost and time are required for forming the insulation layer 16. In practice, the thickness of the insulation layer 16 is up to 50 micrometers, preferably up to 30 micrometers. Therefore, the preferred thickness of the insulation layer 16 is from 2 to 50 micrometers.

The front surface 18a of the insulation layer 16 has a surface roughness in terms of, for example, arithmetic mean roughness Ra, of 1 micrometer or less, preferably 0.5 micrometers or less, and more preferably 0.1 micrometers or less.

The substrate 10 includes the base 12, the Al layer 14 and the insulation layer 16, which are all made of flexible materials, and is therefore flexible as a whole. The lower electrodes 32, the light absorbing layer 34, the upper electrodes 36 and so forth can be thus formed on the insulation layer 16 side of the substrate 10 by, for example, a roll-to-roll system.

In the present invention, the solar cell structure may be produced by continuously forming a plurality of layers during one process from feed-out to roll-up, or the process including the feed-out of the roll, film deposition and roll-up may be performed a plurality of times to prepare the solar cell structure. As will be described later, a scribing step for separating and integrating elements may be added between the respective film deposition steps in the roll-to-roll system to prepare a solar cell structure in which a plurality of solar cells are electrically connected in series.

The manufacturing method of the substrate 10 of the present invention (the composite shown in FIG. 2, before formation of the alloy layer 20) will be described below.

The base 12 is first prepared. The base 12 is formed in a predetermined shape and size suitable to the size of the substrate 10 to be formed.

Then, the Al layer 14 is formed on a surface of the base 12. The method of forming the Al layer 14 on the surface of the base 12 is not particularly limited as long as integral bonding between the base 12 and the Al layer 14 that can ensure adhesion between them is achieved. Examples of the method that may be used include vapor-phase deposition techniques such as vapor deposition and sputtering, electrolytic aluminum plating using a non-aqueous electrolyte, hot dip plating by dipping in molten aluminum, and pressure bonding after surface cleaning. Note that when the Al layer 14 is formed using the hot dip plating method, attention to the thickness of the alloy layer 20 is required, because there is a high likelihood that a thick alloy layer 20 exceeding 10 micrometers will be formed at the interface between the base 12 and the Al layer 14.

The pressure bonding by rolling is preferably used to form the Al layer 14 in terms of the cost and mass production capability.

Next, the surface of the Al layer 14 is anodized to form the insulation layer 16. The substrate 10 is thus obtained.

Various known methods may be used for anodizing aluminum. An example of the method of forming the anodized film serving as the insulation layer 16 is described below.

As described above, the insulation layer 16 is made of an anodized film obtained by anodizing the surface of the Al layer 14. The anodized film can be formed by immersing the base 12 as the anode in an electrolytic solution together with a cathode and applying voltage between the anode and the cathode.

The base 12 forms a local cell with the Al layer 14 upon contact with the electrolytic solution, and therefore the base 12 which contacts the electrolytic solution must be isolated. In other words, it is necessary to isolate the end faces and the back surface (i.e., surface opposite from the surface on which the Al layer 14 was formed) of the base 12 and the lateral surfaces of the Al layer 14 using a masking film or the like.

The surface of the Al layer 14 before anodizing treatment is performed may be optionally subjected to cleaning treatment using an alkali or the like, and/or polishing smoothing treatments such as mechanical polishing and electrolytic polishing.

Carbon or aluminum or the like is used for the cathode in anodization.

The electrolytic solution is not particularly limited, and an acidic electrolytic solution containing one or more acids selected from the group consisting of sulfuric acid, phosphoric acid, chromic acid, oxalic acid, sulfamic acid, benzenesulfonic acid and amidosulfonic acid is preferred. The electrolytic solution preferably contains sulfuric acid, phosphoric acid or oxalic acid, or a mixture thereof.

The anodization conditions vary with the type of electrolyte used and are not particularly limited. As an example, appropriate anodization conditions are an electrolyte concentration of 1 to 80 mass %, a solution temperature of 5 to 70 deg C., a current density of 0.005 to 0.60 A/cm², a voltage of 1 to 200 V and an electrolysis time of 3 to 500 minutes.

During anodization, the oxidation reaction proceeds substantially in the vertical direction from the surface of the Al layer 14 to form the anodized film at the surface of the Al layer 14. In cases where any of the above electrolytic solutions is used, the anodized film is of a porous type in which a large number of fine columns in the shape of a substantially regular hexagon as seen from above are arranged without gaps, and a micropore having a rounded bottom is formed at the core of each fine column, the bottom of each fine column having a barrier layer (typically 0.02 to 0.1 micrometers thick).

As described above, the anodized film having such a porous structure exhibits high bending resistance and high resistance to cracking caused by the difference in thermal expansion at high temperatures.

After forming the porous anodized film using an acidic electrolytic solution, a pore filling technique may be used to perform additional electrolytic treatment in a neutral electrolytic solution in order to increase the thickness of the barrier layer. The insulation properties of the film may be further increased by increasing the thickness of the barrier layer.

In such anodization of aluminum, a dense anodized film (non-porous aluminum oxide single film), rather than an anodized film having porous fine columns arranged therein, is obtained by electrolytic treatment in a neutral electrolytic solution such as boric acid rather than an acidic electrolytic solution.

As described above, the anodized film serving as the insulation layer 16 preferably has a thickness of 2 to 50 micrometers. The thickness can be controlled by the electrolysis time and the magnitudes of the current and voltage in constant current electrolysis or constant voltage electrolysis.

Anodizing treatment can be performed using, for example, a known anodizing apparatus of a so-called roll-to-roll system.

The masking film is peeled off after anodizing treatment. The substrate 10 can be thus produced. Note that formation of the alloy layer 20 will be described in detail below.

As described above, the solar cell 30 shown in FIG. 1 is a solar cell module (module-type solar cell) in which thin-film solar cells 40 comprising lower electrodes 32, light absorbing layer 34, buffer layer 36 and upper electrodes 38 are joined in series on the substrate 10.

Also, as described above, the substrate 10 is basically constructed from the base 12, Al layer 14 and insulation layer 16, and also, an alloy layer 20 of thickness 0.01 to 10 micrometers is formed between the base 12 and the Al layer 14. Due to the fact that the substrate 10 (solar cell 30 (semiconductor device)) of the present invention has such an alloy layer 20, cracking and delamination of the Al layer 14 and insulation layer 16 are suitably inhibited, and a substrate 10 that has excellent insulation characteristics and mechanical strength and that can be manufactured by a roll-to-roll system can be realized, and a semiconductor device such as the solar cell 30 can be realized.

Although also illustrated in the working examples below, in the substrate 10 of the present invention, the alloy layer 20 (inter-metallic layer 20) generated at the interface between the base 12 and the Al layer 14 is an aluminum alloy corresponding to the type of base 12, and is assumed to be a layer made up primarily of an intermetallic compound (IMC). Specifically, if the base 12 is iron, the alloy layer 20 is assumed to be Al₃Fe; if the base 12 is titanium, it is assumed to be Al₃Ti; and if the base 12 is iron-based alloy steel, it is assumed to be a layer in which an alloy element is in solid solution at the Fe sites of Al₃Fe.

Here, no matter which base 12 is used, the Al layer 14 diminishes due to the generation (growth) of the alloy layer 20, but the base 12 undergoes almost no diminishment.

If there is no alloy layer 20 present at all, the interface adhesion between the base 12 and the Al layer 14 is poor, and when thermal cycling or bending stress is applied during the roll-to-roll manufacturing process or during use of the semiconductor devices, interface delamination occurs between the base 12 and the Al layer 14, causing delamination or cracking of the insulation layer.

Conversely, if the alloy layer 20 is too thick, the intermetallic compound that primarily forms the alloy layer 20 is brittle, and as the thick alloy layer 20 is formed, voids and cracks occur between the alloy layer 20 and the Al layer 14, and this causes interface delamination and loss of insulation function.

According to studies by the inventors, the thickness of the alloy layer 20 must be 0.01 micrometers or more in order to avoid the problems described above and to suitably realize the effect of having an alloy layer 20. For the same reason, the thickness of the alloy layer 20 must be 10 micrometers or less, and 5 micrometers or less is particularly preferred.

Note that in the semiconductor device of the present invention, the thickness of the alloy layer 20 means the thickness at the point when the semiconductor device such as the solar cell 30 has been completed.

That is, by setting the thickness of the alloy layer 20 to 0.01 to 10 micrometers, interface adhesion can be appropriately assured due to the fact that there is an alloy layer 20, and in addition, insulation characteristics can be suitably assured and the occurrence of interface delamination and curling can be appropriately suppressed, even when voids and so forth arising in the alloy layer 20 are generated. In particular, by setting the thickness of the alloy layer 20 to 0.01 to 5 micrometers, the generation of voids and so forth can be more appropriately suppressed, the occurrence of interface delamination and curling can be more reliably suppressed, and the decrease in insulation performance caused by them can be suppressed.

Although illustrated in the working examples below, note that if the alloy layer 20 is thin, it is often the case that the alloy layer 20 is generated in the form of islands at the interface between the base 12 and the Al layer 14. Even with this type of island-form alloy layer 20, the effect of having the alloy layer 20 is suitably realized.

Note that in the present invention, the thickness of the alloy layer 20 means the average thickness of a cross-section of the base 12 (insulating metal substrate). Also, the average thickness of the cross-section of the base 12 may be measured by observing the cross-section of the base 12.

Specifically, although illustrated in the working examples below, the thickness of the alloy layer 20 is determined by slicing the base 12 (semiconductor device such as a solar cell 30) to reveal the cross-section of the base 12, and then photographing this cross-section by SEM (scanning electron microscope) or the like, measuring the area of the alloy layer 20 in the photograph by image analysis, and dividing by the length of the field of observation.

As described above, if the alloy layer 20 is thin, the alloy layer 20 is generated in the form of islands at the interface between the base 12 and the Al layer 14. Even in this case, the thickness of the alloy layer 20 may be taken as the average thickness as described above, rather than the thickness of each island.

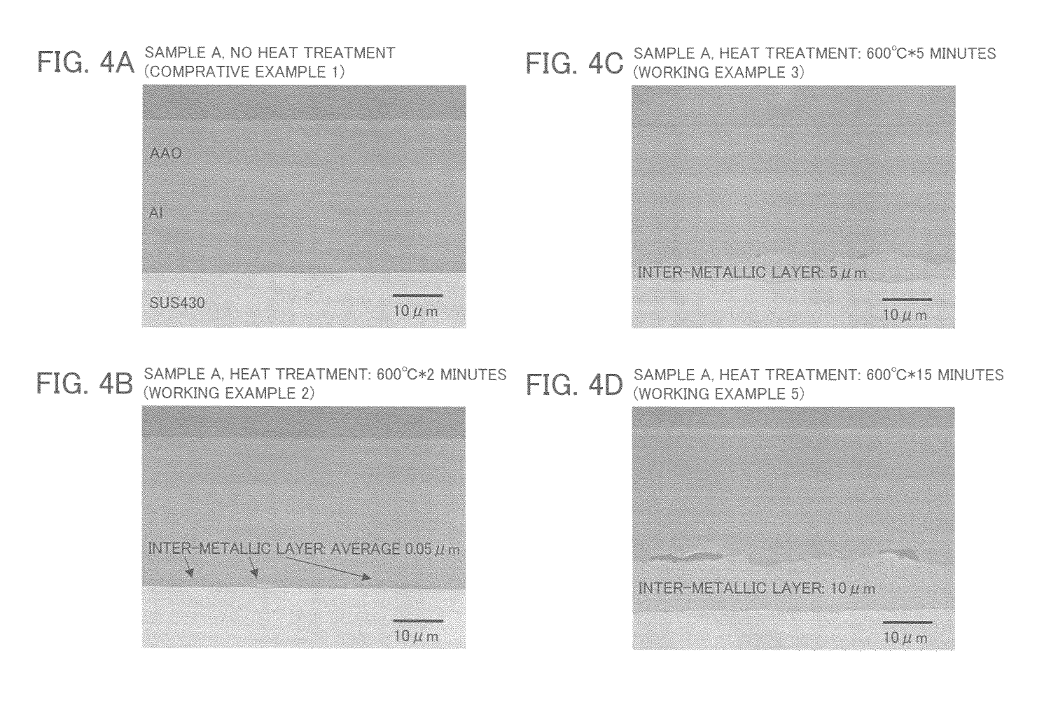

Here, as shown in FIG. 4, the thickness of the alloy layer 20 is not uniform, and the alloy layer 20 has many hills and valleys.

However, although many hills and valleys can be seen, the alloy layer 20 normally grows approximately uniformly. Growth in faceted shapes, growth in whisker shapes and abnormal growth that greatly eats into the base 12 or Al layer 14 do not occur. Therefore, the thickness of the alloy layer 20 can be accurately measured by the above measurement method using a photographed image.

An example of the method of formation of the alloy layer 20 is a method wherein the Al layer 14 is formed on the front surface of the base 12 as described above, and then this composite is heat-treated. Or, it may be a method wherein a composite having the base 12, Al layer 14 and insulation layer 16 as shown in FIG. 2 is produced, and then heat treatment is performed, thereby forming the alloy layer 20.

Also, if a certain degree of sealing between the base 12 and the Al layer 14 of the above composite is to be assured, instead of (or in addition to) formation of the alloy layer 20 by heat treatment of the composite, a high-temperature process in the manufacture of a portion of the semiconductor element after substrate production, such as deposition of the light absorbing layer 34 described below, may also serve as the formation process of the alloy layer 20.

Here, the thickness of the alloy layer 20 differs depending on the reactivity between aluminum and the material of the base 12, but it is basically determined by the thermal history (temperature and time) undergone by the substrate 10.

Therefore, the heat treatment conditions (holding temperature and holding time=thermal history) that will result in the desired thickness of the alloy layer 20 in the range of 0.01 to 10 micrometers (preferably 0.01 to 5 micrometers) are examined in advance either experimentally or by simulation in accordance with the combination of the base 12 and Al layer 14, and as a result, heat treatment of the composite as described above can be performed accordingly. Also, in cases where there is a high-temperature process such as a deposition process of the light absorbing layer 34 in the manufacturing process of the semiconductor devices such as the solar cell 30, the treatment conditions in the high-temperature process can be set such that the alloy layer 20 has the desired thickness.

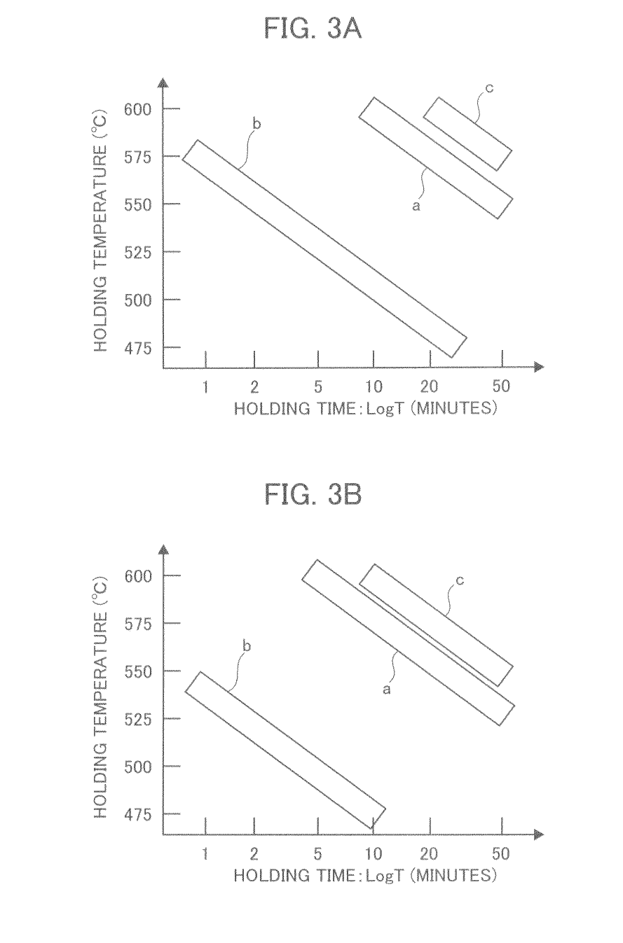

FIG. 3A illustrates the heat treatment conditions that result in an alloy layer 20 of thickness 10 micrometers generated at the interface between the base 12 and Al layer 14, in the format of a TTT (time temperature transformation) diagram.

In the example shown in FIG. 3A, the Al layer 14 is high-purity aluminum of purity 4N. Also, a is an example in which the base 12 is ferritic stainless steel (SUS430), b is example in which the base 12 is low-carbon steel (SPCC), and c is an example in which the base 12 is high-purity titanium material of 99.5% purity.

As shown in FIG. 3A, the heat treatment conditions that result in an alloy layer 20 of thickness 10 micrometers are such that the higher the holding temperature, the shorter the time, or the longer the holding time, the lower the temperature.

If the base 12 is low-carbon steel, when the holding temperature is 500 deg C., for example, the thickness of the alloy layer 20 is 10 micrometers with a holding time of about 10 minutes, as indicated by b in FIG. 3A. Therefore, in the manufacturing process of a semiconductor device such as the solar cell 30, if treatment is performed at 500 deg C., the thickness of the alloy layer 20 will be 10 micrometers or less if the treatment time is 10 minutes or less. Conversely, if treatment is performed for 10 minutes, the thickness of the alloy layer 20 will be 10 micrometers or less if the treatment temperature is 500 deg C. or less.

Also, if the base 12 is low-carbon steel, when the holding temperature is 525 deg C., the thickness of the alloy layer 20 is 10 micrometers with a holding time of about 5 minutes. Therefore, in the manufacturing process of a semiconductor device such as the solar cell 30, if treatment is performed at 525 deg C., the thickness of the alloy layer 20 will be 10 micrometers or less if the treatment time is 5 minutes or less. Conversely, if treatment is performed for 5 minutes, the thickness of the alloy layer 20 will be 10 micrometers or less if the treatment temperature is 525 deg C. or less.

In other words, in the present invention, when treatment is performed at 500 deg C. during the manufacturing process, low-carbon steel can be used as the base 12 if the treatment time is 10 minutes or less, and when treatment is performed for 10 minutes, low-carbon steel can be used as the base 12 if the treatment temperature is 500 deg C. or less.

Also, when treatment is performed at 525 deg C. in the manufacturing process, low-carbon steel can be used as the base 12 if the treatment time is 5 minutes or less, and when treatment is performed for 5 minutes, low-carbon steel can be used as the base 12 if the treatment temperature is 525 deg C. or less.

If the base 12 is ferritic stainless steel, as indicated by a in FIG. 3A, the heat treatment conditions that result in an alloy layer 20 of 10 micrometers consist of a higher temperature and longer time.

If the base 12 is ferritic stainless steel, if the holding temperature is 575 deg C., for example, an alloy layer 20 of 10 micrometers will be produced with a holding time of 20 minutes. That is, if a semiconductor device such as a solar cell 30 is produced using ferritic stainless steel as the base 12, treatment up to 20 minutes is possible when treatment is at 575 deg C., and conversely, high-temperature treatment up to 575 deg C. is possible when treatment is performed for 20 minutes.

In other words, when treatment is performed at 575 deg C., ferritic stainless steel can be used as the base 12 if the treatment time is 20 minutes or less, and when treatment is performed for 20 minutes, ferritic stainless steel can be used as the base 12 if the treatment temperature is 575 deg C. or less.

Also, as indicated by c in FIG. 3A, if the base 12 is titanium material, heat treatment at a higher temperature and for a longer time is possible, such as a treatment temperature of 580 deg C. or below and/or a treatment time of 50 minutes or less.

FIG. 3B shows the heat treatment conditions that result in an alloy layer 20 of thickness 5 micrometers between the same Al layer 14 and base 12. Note that in the diagram, a, b and c are the same as in FIG. 3A.

As shown in FIG. 3B, the heat treatment conditions that result in an alloy layer 20 of thickness 5 micrometers are a lower temperature and shorter time than for a thickness of 10 micrometers.

However, as indicated by b in FIG. 3B, even if low-carbon steel is used as the steel base 12, for example, when the treatment temperature is 500 deg C., the thickness of the alloy layer 20 is 5 micrometers or less if the treatment time is 5 minutes or less. That is, when treatment is performed at 500 deg C., low-carbon steel can be used as the base 12 if the treatment time is 5 minutes or less, and when treatment is performed for 5 minutes, low-carbon steel can be used as the base 12 if the treatment temperature is 500 deg C. or less.

Also, as indicated by a in FIG. 3B, if ferritic stainless steel is used as the base 12, treatment can be performed for 20 minutes at 550 deg C., for example, even when the desired thickness of the alloy layer 20 is 5 micrometers or less. Also, as indicated by c in FIG. 3B, if titanium material is used as the base 12, treatment can be performed for 20 minutes at 575 deg C., for example, even when the desired thickness of the alloy layer 20 is 5 micrometers or less.

That is, no matter which base 12 is used, under the heat treatment conditions (thermal history) shown in FIG. 3, the thickness of the alloy layer 20 of the substrate 10 can be 10 micrometers or less, provided that the heat treatment conditions are in the region below and to the left of the region that results in an alloy layer 20 thickness of 10 micrometers (5 micrometers).

Therefore, in the manufacturing process of the substrate 10 that uses these bases 12 and semiconductor devices such as the solar cell 30, treatment can be performed under conditions in the region below and to the left of the region that results in an alloy layer 20 thickness of 10 micrometers, and formation of light absorbing layers 34 can be performed at 500 deg C. or above, for example, by selecting the base materials and the film deposition conditions.

Note that in each base 12, the reason that the region that results in an alloy layer 20 thickness of 10 micrometers (5 micrometers) has a band shape is that, as described above, the thickness of the alloy layer 20 is not uniform on the entire surface, and there are hills and valleys.

Therefore, basically, in each base 12, if the heat treatment conditions are in the region below and/or to the left of the upper line of the band that results in thickness of 10 micrometers, the thickness of the alloy layer 20 can be 10 micrometers or less. Additionally, in cases where it is desired to more reliably ensure that the thickness of the alloy layer 20 is 10 micrometers or less, it is preferred that the heat treatment conditions are in the region below and/or to the left of the lower line of the band that results in thickness of 10 micrometers.

In the manufacturing process of a semiconductor device such as the solar cell 30, if the substrate 10 incurs high temperature multiple times, since it can be thought that the principle of addition holds true, the thickness of the alloy layer 20 can be 10 micrometers (5 micrometers) or less by adding the temperature and the treatment time of each heat treatment.

Also, FIG. 3 shows only some of the heat treatment conditions that result in an alloy layer 20 thickness of 10 micrometers, and according to studies by the present inventors, the region that results in an alloy layer 20 thickness of 10 micrometers may be extended linearly on the high-temperature side to near 660 deg C., which is the melting point of aluminum, and on the low-temperature side to the minimum temperature at which IMC is produced.

The solar cell 30 is a solar cell module in which thin-film solar cells 40 comprising lower electrodes 32, light absorbing layer 34, buffer layer 36 and upper electrodes 38 are joined in series on the substrate 10.

Also, a first conductive member 42 and a second conductive member 44 are formed on the lower electrodes 32 on the two ends in the direction of array.

In a preferred aspect shown in the drawings, an alkali supply layer 50 is formed between the insulation layer 16 (substrate 10) and the lower electrodes 32.

It is known that the alkali metal (particularly sodium) has high photoelectric conversion efficiency when diffused into the light absorbing layer 34 made of a material such as CIGS. The alkali supply layer 50 is a layer for supplying alkali metal to the light absorbing layer 34, and is a layer of an alkali metal-containing compound. By having this alkali supply layer 50, the alkali metal diffuses through the lower electrodes 32 into the light absorbing layer 34 during the formation of the light absorbing layer 34, thus enabling the conversion efficiency of the light absorbing layer 34 to be improved.

The alkali supply layer 50 is not particularly limited, and various materials consisting primarily of an alkali metal-containing compound (composition containing an alkali metal compound) such as Na₂O, Na₂S, Na₂Se, NaCl, NaF or sodium molybdate may be used. SiO₂ (silicon dioxide)-based compounds containing Na₂O (sodium oxide) are particularly preferred.

The method of forming the alkali supply layer 50 is not particularly limited, and various known methods may be used. Exemplary methods include vapor-phase deposition methods such as sputtering and CVD, and liquid-phase deposition methods such as the sol-gel method.

For example, in the case of a SiO₂-based compound containing Na₂O, the alkali supply layer 50 can be formed by sputtering using soda-lime glass as the target or a sol-gel reaction using an alkoxide containing silicon and sodium. These methods may also be used in combination.

Note that in the present invention, the source of alkali metal supply to the light absorbing layer 34 is not limited to only the alkali supply layer 50, and in the case where the insulation layer 16 is porous, the alkali supply source may be an alkali metal compound of porosity less than or equal to that of the insulation layer 16. Also, the alkali supply layer 50 and the alkali metal compound with the above porosity may be used in combination.

In the solar cell 30, the lower electrodes 32 are formed on the alkali supply layer 50 such that they are separated from neighboring lower electrodes 32 by predetermined spaces 33. The light absorbing layer 34 is formed on the lower electrodes 32 so as to fill the spaces 33 between the neighboring lower electrodes 32. The buffer layer 36 is formed on a surface of the light absorbing layer 34.

The light absorbing layer 34 and the buffer layer 36 are arranged on the lower electrodes 32 so as to have predetermined spaces 37 therein. The spaces 33 between the neighboring lower electrodes 32 and the spaces 37 in the light absorbing layer 34 (buffer layer 36) are formed at different positions in the direction of array of the thin-film solar cells 40.

The upper electrodes 38 are formed on a surface of the buffer layer 36 so as to fill the spaces 37 in the light absorbing layer 34 (buffer layer 36).

The upper electrodes 38, the buffer layer 36 and the light absorbing layer 34 are disposed so as to have predetermined spaces 39. The spaces 39 are provided at different positions from the spaces between the neighboring lower electrodes 32 and the spaces in the light absorbing layer 34 (buffer layer 36).

In the solar cell 30, the respective thin-film solar cells 40 are electrically connected in series in the longitudinal direction of the substrate 10 (in the direction indicated by arrow L) through the lower electrodes 32 and the upper electrodes 38.

The lower electrodes 32 are, for example, molybdenum electrodes. The light absorbing layer 34 is made of a semiconductor compound having a photoelectric conversion function and is, for example, a GIGS layer. In addition, the buffer layer 36 is made of, for example, CdS, and the upper electrodes 38 are made of, for example, ZnO.

The thin-film solar cells 40 are formed so as to extend in the width direction perpendicular to the longitudinal direction L of the substrate 10. Therefore, the lower electrodes 32 also extend in the width direction of the substrate 10.

As shown in FIG. 1, the first conductive member 42 is connected to the rightmost lower electrode 32. The first conductive member 42 is provided to collect the output from a negative electrode to be described later.

The first conductive member 42 is, for example, a member in the shape of an elongated strip which extends substantially linearly in the width direction of the substrate 10 and is connected to the rightmost lower electrode 32. As shown in FIG. 1, the first conductive member 42 has, for example, a copper ribbon 42a covered with a coating material 42b made of an alloy of indium and copper. The first conductive member 42 is connected to the lower electrode 32 by, for example, ultrasonic soldering.

On the other hand, the second conductive member 44 is formed on the leftmost lower electrode 32.

The second conductive member 44 is provided to collect the output from a positive electrode to be described later. As in the first conductive member 42, the second conductive member 44 is a member in the shape of an elongated strip which extends substantially linearly in the width direction of the substrate 10 and is connected to the leftmost lower electrode 32.

The second conductive member 44 is composed similarly to the first conductive member 42 and has, for example, a copper ribbon 44a covered with a coating material 44b made of an alloy of indium and copper.

The light absorbing layer (photoelectric conversion layer) 34 in the thin-film solar cells 40 of the embodiment under consideration is made of, for example, GIGS, and can be manufactured by a known method of manufacturing GIGS solar cells.

In the solar cell 30, light entering the thin-film solar cell 40 from the side of the upper electrode 38 passes through the upper electrode 38 and the buffer layer 36 and causes electromotive force to be generated in the light absorbing layer 34, thus producing a current that flows, for example, from the upper electrode 38 to the lower electrode 32. Note that the arrows shown in FIG. 1 indicate the direction of the current, and the direction in which electrons move is opposite to that of current. Therefore, in the thin-film solar cells 40, the leftmost lower electrode 32 in FIG. 1 has a positive pole (anode) and the rightmost lower electrode 32 has a negative pole (cathode).

In the embodiment under consideration, electric power generated in the solar cell 30 can be output from the solar cell 30 through the first conductive member 42 and the second conductive member 44.

Also, in the embodiment under consideration, the first conductive member 42 has a negative polarity, and the second conductive member 44 has a positive polarity. The polarities of the first conductive member 42 and the second conductive member 44 may be reversed; their polarities may vary according to the configuration of the thin-film solar cells 40, the configuration of the solar cell 30, and the like.

In the embodiment under consideration, the thin-film solar cells 40 formed are connected in series in the longitudinal direction L of the substrate 10 through the lower electrodes 32 and the upper electrodes 38, but this is not the sole case of the present invention. For example, the thin-film solar cells 40 may be formed so as to be connected in series in the width direction through the lower electrodes 32 and the upper electrodes 38.

The lower electrodes 32 and the upper electrodes 38 of the thin-film solar cells 40 are provided to collect the current generated in the light absorbing layer 34. Both the lower electrodes 32 and the upper electrodes 38 are made of a conductive material. The upper electrodes 38 provided on the light incident side must be pervious to light.

The lower electrodes (back electrodes) 32 are made of, for example, molybdenum, chromium or tungsten, or a combination thereof. The lower electrodes 32 may be of a single-layer structure or a laminated structure such as a dual-layer structure. The lower electrodes 32 are preferably made of molybdenum.

The lower electrodes 32 preferably have a thickness of 100 nm or more, and more preferably 0.45 to 1.0 micrometers.

The method of forming the lower electrodes 32 is not particularly limited, and the lower electrodes 32 may be formed by vapor-phase deposition techniques such as electron beam evaporation and sputtering.

The upper electrodes (transparent electrodes) 38 are made of, for example, ZnO doped with Al, B, Ga, Sb, etc., ITO (indium tin oxide), SnO₂, or a combination of two or more thereof. The upper electrodes 38 may be of a single-layer structure or a laminated structure such as a dual-layer structure. The thickness of the upper electrodes 38 is not particularly limited, but is preferably from 0.3 to 1 micrometers.

The method of forming the upper electrodes 38 is not particularly limited, and the upper electrodes 38 may be formed by vapor-phase deposition techniques such as electron beam evaporation and sputtering or a coating method.

The buffer layer 36 is provided to protect the light absorbing layer 34 during the formation of the upper electrodes 38, and allows the light that passed through the upper electrodes 38 to enter the light absorbing layer 34.

The buffer layers 36 are made of, for example, CdS, ZnS, ZnO, ZnMgO or ZnS (O, OH) or a combination thereof.

The buffer layers 36 preferably have a thickness of 0.03 to 0.1 micrometers. The buffer layers 36 are formed by, for example, chemical bath deposition (CBD).

The light absorbing layer 34 absorbs light that reached through the upper electrodes 38 and the buffer layer 36 to generate current, and has a photoelectric conversion function. According to this embodiment, the light absorbing layer 34 is not particularly limited in structure; the light absorbing layer 34 is made of, for example, at least one compound semiconductor having a chalcopyrite structure. The light absorbing layer 34 may be made of at least one compound semiconductor composed of a group Ib element, a group IIIb element and a group VIb element.

For higher optical absorbance and higher photoelectric conversion efficiency, the light absorbing layer 34 is preferably made of at least one compound semiconductor composed of at least one group Ib element selected from Cu and Ag, at least one group IIIb element selected from the Al, Ga and In, and at least one group VIb element selected from S, Se and Te. Examples of the compound semiconductor include CuAlS₂, CuGaS₂, CuInS₂CuAlSe₂, CuGaSe₂, CuInSe₂ (CIS), AgAlS₂, AgGaS₂, AgInS₂, AgAlSe₂, AgGaSe₂, AgInSe₂, AgAlTe₂, AgGaTe₂, AgInTe₂, Cu(In₁₋ₓGaₓ)Se₂ (CIGS), Cu(In₁₋ₓAlₓ)Se₂, Cu(In₁₋ₓGaₓ)(S,Se)₂, Ag(In₁₋ₓGaₓ)Se₂ and Ag(In₁₋ₓGaₓ)(S,Se)₂.

The light absorbing layers 34 preferably contain CuInSe₂ (CIS) and/or Cu(In,Ga)Se₂ (CIGS), which is obtained by dissolving gallium in the former. CIS and CIGS are semiconductors each having a chalcopyrite crystal structure, which reportedly have high optical absorbance and high photoelectric conversion efficiency. Further, they have little deterioration of efficiency under exposure to light, and exhibit excellent durability.

The light absorbing layer 34 contains impurities for obtaining the desired semiconductor conductivity type. Impurities may be incorporated in the light absorbing layer 34 by diffusion from a neighboring layer and/or active doping. The light absorbing layer 34 may have concentration distributions for the elements making up the group semiconductor and/or impurities; the light absorbing layer 34 may contain a plurality of layer regions of different semiconductivities such as n-type, p-type, and i-type.

For example, in a GIGS type, the light absorbing layer 34, which has a distribution of the Ga amount in the thickness direction, enables the band gap width and carrier mobility to be controlled to achieve design with high photoelectric conversion efficiency.

The light absorbing layer 34 may contain one or more semiconductor other than group semiconductors.

Examples of the semiconductor other than the group semiconductors include a semiconductor made of a group IVb element such as Si (group IV semiconductor), a semiconductor made of a group IIIb element and a group Vb element (group III-V semiconductor) such as GaAs, and a semiconductor made of a group IIb element and a group VIb element (group II-VI semiconductor) such as CdTe. The light absorbing layer 34 may contain any component other than the semiconductor and impurities used to obtain the desired conductivity type, provided that the properties are not adversely affected thereby.

The content of the group semiconductor in the light absorbing layer 34 is not particularly limited. The content of the group semiconductor in the light absorbing layer 34 is preferably at least 75 mass %, more preferably at least 95 mass % and most preferably at least 99 mass %.

Note that in this example, if the light absorbing layer 34 is constructed from a compound semiconductor of which the primary component (at least 75 mass %) is CdTe, the base 12 is preferably constructed from carbon steel or ferritic stainless steel.

Exemplary known methods of forming the CIGS layer include 1) simultaneous multi-source evaporation, 2) selenization, 3) sputtering, 4) hybrid sputtering and 5) mechanochemical processing.

1) Known multi-source co-evaporation methods include: the three-stage method (J. R. Tuttle et al., Mat. Res. Soc. Symp. Proc., Vol. 426 (1966), p. 143, etc.), and the co-evaporation method of the EC group (L. Stolt et al.: Proc. 13th ECPVSEC (1995, Nice), 1451, etc.).

According to the former three-phase method, firstly, In, Ga and Se are simultaneously evaporated under high vacuum at a substrate temperature of 300 deg C., which is then increased to 500 deg C. to 560 deg C. to simultaneously vapor-deposit Cu and Se, whereupon In, Ga and Se are further simultaneously evaporated. The latter simultaneous evaporation method by EC group is a method which involves evaporating copper-excess CIGS in the earlier stage of evaporation, and evaporating indium-excess CIGS in the latter half of the stage.

Improvements have been made on the foregoing methods to improve the crystallinity of CIGS films, and the following methods are known:

a) Method using ionized Ga (H. Miyazaki et al., Phys. Stat. Sol. (a), Vol. 203 (2006), p. 2603, etc.);
b) Method using cracked selenium (a pre-printed collection of presentations given at the 68th Academic Lecture by the Japan Society of Applied Physics) (autumn, 2007, Hokkaido Institute of Technology), 7P-L-6, etc.)
c) Method using radicalized selenium (a pre-printed collection of presentations given at the 54th Academic Lecture by the Japan Society of Applied Physics) (spring, 2007, Aoyama Gakuin Univ.), 29P-ZW-10, etc.); and
d) Method using a light excitation process (a pre-printed collection of presentations given at the 54th Academic Lecture by the Japan Society of Applied Physics) (spring, 2007, Aoyama Gakuin Univ.), 29P-ZW-14, etc.).

2) The selenization method is also called the two-stage method, whereby, firstly, a metal precursor formed of a laminated film such as a copper layer/indium layer, a (copper-gallium) layer/indium layer or the like is formed by sputter deposition, vapor deposition, or electrodeposition, and the film thus formed is heated in selenium vapor or hydrogen selenide to a temperature of 450 deg C. to 550 deg C. to produce a selenide such as Cu(In₁₋ₓGaₓ)Se₂ by thermal diffusion reaction. This method is called vapor-phase selenization. Another exemplary method is solid-phase selenization in which solid-phase selenium is deposited on a metal precursor film and selenized by a solid-phase diffusion reaction using the solid-phase selenium as the selenium source.

In order to avoid abrupt volume expansion that may take place during the selenization, selenization is implemented by known methods including a method in which selenium is previously mixed into the metal precursor film at a given ratio (T. Nakada et al., Solar Energy Materials and Solar Cells 35 (1994), 204-214, etc.); and a method in which selenium is sandwiched between thin metal films (e.g., as in Cu layer/In layer/Se layer . . . Cu layer/In layer/Se layer) to form a multi-layer precursor film (T. Nakada et al., Proc. of 10th European Photovoltaic Solar Energy Conference (1991), 887-890, etc.).

An exemplary method of forming a graded band gap CIGS film is a method which involves first depositing a copper-gallium alloy film, depositing an indium film thereon and selenizing with a gallium concentration gradient in the film thickness direction making use of natural thermal diffusion (K. Kushiya et al., Tech. Digest 9th Photovoltaic Science and Engineering Conf. Miyazaki, 1996 (Intn. PVSEC-9, Tokyo, 1996), p. 149, etc.).

3) Known sputtering techniques include:

a technique using CuInSe₂ polycrystal as a target, one called two-source sputtering using H₂Se/Ar mixed gas as sputter gas with Cu₂Se and In₂Se₃ as targets (J. H. Ermer et al., Proc. 18th IEEE Photovoltaic Specialists Conf. (1985), 1655-1658, etc.) and a technique called three-source sputtering whereby a Cu target, an In target, and an Se or CuSe target are sputtered in Ar gas (T. Nakada et al., Jpn. J. Appl. Phys. 32 (1993), L1169-L1172, etc.).

4) Exemplary known methods for hybrid sputtering include one in which Cu and In metals are subjected to DC sputtering, while only Se is vapor-deposited in the aforementioned sputter deposition method (T. Nakada, et al., Jpn. Appl. Phys. 34 (1995), 4715-4721, etc.).

5) An exemplary method for mechanochemical processing includes a method in which a material selected according to the CIGS composition is placed in a planetary ball mill container and mixed by mechanical energy to obtain pulverized CIGS, which is then applied to a substrate by screen printing and annealed to obtain a CIGS film (T. Wada et al., Phys. Stat. Sol. (a), Vol. 203 (2006), p. 2593, etc.).

Other exemplary methods for forming a CIGS film include screen printing, close-spaced sublimation, MOCVD, and spraying (wet deposition). For example, crystals with a desired composition can be obtained by a method which involves forming a fine particle film containing a group Ib element, a group IIIb element and a group VIb element on a substrate by, for example, screen printing (wet deposition) or spraying (wet deposition) and subjecting the fine particle film to pyrolysis treatment (which may be a pyrolysis treatment carried out under a group VIb element atmosphere) (JP 9-74065 A, JP 9-74213 A, etc.).

In the embodiment under consideration, the difference between the linear expansion coefficient of the base 12 and that of the light absorbing layer 34 is preferably less than 3×10⁻⁶/deg C.

Of the main compound semiconductors for use in the light absorbing layer 34, GaAs as a typical group III-V compound semiconductor has a linear expansion coefficient of 5.8×10⁻⁶/deg C., CdTe as a typical group II-VI compound semiconductor has a linear expansion coefficient of 4.5×10⁻⁶/deg C., and Cu(InGa)Se₂ as a typical group compound semiconductor has a linear expansion coefficient of 10×10⁻⁶/deg C.

A large thermal expansion difference between the base 12 and the light absorbing layer 34 may cause a film deposition defect such as delamination upon cooling of the compound semiconductor deposited on the substrate 10 at a high temperature of at least 500 deg C. as the light absorbing layer 34. A large internal stress of the compound semiconductor due to the difference in the thermal expansion from the base 12 may reduce the photoelectric conversion efficiency of the light absorbing layer 34. A difference in the linear expansion coefficient between the base 12 and the light absorbing layer 34 (compound semiconductor) of less than 3×10⁻⁶/deg C. does not readily cause delamination or other film deposition defects, and is therefore preferred. The difference in the linear expansion coefficient is more preferably less than 1×10⁻⁶/deg C. The linear expansion coefficient and the difference in the linear expansion coefficient are those obtained at room temperature (23 deg C.).

As described above, the solar cell 30 of the present invention is manufactured by joining in series the thin-film solar cells 40 on the foregoing substrate 10, but may be manufactured by the same method as used to manufacture various known solar cells.

An example of the method of manufacturing the solar cell 30 shown in FIG. 1 is described below.

The substrate 10 formed as described above (or a composite serving as the substrate 10) is first prepared. Then, the alkali supply layer 50 is formed on the surface of the insulation layer 16 of the substrate 10 by, for example, sputtering using soda-lime glass as a target or the sol-gel method using an alkoxide containing silicon and sodium.

Then, a molybdenum film serving as the lower electrodes 32 is formed by sputtering on the surface of the alkali supply layer 50 using, for example, a film deposition apparatus.

Then, for example, laser scribing is used to scribe the molybdenum film at predetermined positions to form the spaces 33 extending in the width direction of the substrate 10. The lower electrodes 32 separated from each other by the spaces 33 are thus formed.

Then, the lower electrodes 32 are covered with the light absorbing layer 34 (p-type semiconductor layer) so as to fill the spaces 33.

The light absorbing layer 34 is, for example, a GIGS layer, and may be formed by any known film deposition method as described above.

Here, it is preferred that the light absorbing layer 34 comprising the compound semiconductor of GIGS or the like is formed at a film deposition temperature of at least 500 deg C. as described above, because the conversion efficiency of the solar cell is better when it is formed at high temperature. Thus, in the manufacture of the solar cell 30, the alloy layer 20 can be generated at the interface between the base 12 and the Al layer 14 of the substrate 10 at the time when the light absorbing layer 34 is deposited.

Therefore, considering the heat treatment conditions which result in an alloy layer 20 thickness of 10 micrometers as shown in FIG. 3, the deposition conditions of the light absorbing layer 34 are preferably set such that the alloy layer 20 is 0.01 to 10 micrometers, more preferably 0.01 to 5 micrometers, in accordance with the material of the base 12 and so forth.

Note that in the manufacture of a solar cell which uses a semiconductor compound as the light absorbing layer 34, in general, high-temperature treatments that result in generation of the alloy layer 20 are prohibited in manufacturing processes other than deposition of the light absorbing layer 34. Therefore, in these processes, there is no particular need to consider generation of the alloy layer 20.

Once the light absorbing layer 34 is deposited, a CdS layer (n-type semiconductor layer) serving as the buffer layer 36 is formed on the GIGS layer by, for example, chemical bath deposition (CBD). A p-n junction semiconductor layer is thus formed.

Then, for example, laser scribing is used to scribe the thin-film solar cells 40 at predetermined positions different from those at which the spaces 33 have been formed, to thereby form the spaces 37 which extend in the width direction of the substrate 10 and reach the lower electrodes 32.

Then, a layer of ZnO doped with Al, B, Ga, Sb or the like which serves as the upper electrodes 38 is formed on the buffer layer 36 by sputtering or coating so as to fill the spaces 37.

Then, for example, laser scribing is used to scribe the thin-film solar cells 40 at predetermined positions different from those at which the spaces 33 and 37 have been formed, to thereby form the spaces 39 which extend in the width direction of the substrate 10 and reach the lower electrodes 32. The thin-film solar cells 40 are thus formed.

Then, the thin-film solar cells 40 formed on the rightmost and leftmost lower electrodes 32 in the longitudinal direction L of the substrate 10 are removed by, for example, laser scribing or mechanical scribing to expose the lower electrodes 32. Then, the first conductive member 42 and the second conductive member 44 are connected by, for example, ultrasonic soldering onto the rightmost and leftmost lower electrodes 32, respectively.

The solar cell 30 in which the thin-film solar cells 40 are electrically connected in series can be thus manufactured as shown in FIG. 2.

If necessary, a bond/seal layer, a water vapor barrier layer and a surface protection layer are disposed on the top side of the resulting solar cell 30 and a bond/seal layer and a back sheet are formed on the back side of the solar cell 30—that is, on the back side of the substrate 10—and these layers are integrated by vacuum lamination.

The above example is one in which the semiconductor device of the present invention is used in a solar cell (module), but the semiconductor device of the present invention is not limited thereto, and semiconductor devices in which a plurality of various semiconductor elements are arranged in an array on the insulating metal substrate of the present invention may be variously used. That is, the present invention may be used in various semiconductor devices formed by changing the glass substrate used in devices in which semiconductor circuits are formed on a conventional glass substrate, to the insulating metal substrate of the present invention.

Preferred examples include passive devices such as sensors, and TFT panels used for driving organic EL displays.

While the insulating metal substrate and semiconductor device according to the present invention have been described above in detail, the present invention is by no means limited to the foregoing examples and various improvements, and modifications may of course be made without departing from the spirit of the present invention.

### EXAMPLES

Next, the present invention is described in further detail by referring to specific working examples of the insulating metal substrate of the present invention.

Sample A

A commercially available ferritic stainless steel (SUS430) and high-purity aluminum (aluminum purity: 4N) were joined by cold rolling to prepare a two-layer clad material including an Al layer 14 with a thickness of 30 micrometers and a base 12 (stainless steel) with a thickness of 50 micrometers.

The base surface and end surfaces were covered with a masking film, after which it was ultrasonically cleaned with ethanol, and electrolytically polished with a solution of acetic acid and perchloric acid. After that, an insulation layer 16 (anodized film of aluminum) was formed at a thickness of 10 micrometers by constant-voltage electrolysis at 40 V in an 80 g/L oxalic acid solution, and the substrate 10 shown in FIG. 1A was produced.

Note that the thickness of the Al layer 14 after insulation layer formation was 20 micrometers.

Sample B

A commercially available low-carbon steel (SPCC) and high-purity aluminum (aluminum purity: 4N) were joined by cold rolling to prepare a two-layer clad material containing an Al layer 14 with a thickness of 30 micrometers and a base 12 (low-carbon steel) with a thickness of 50 micrometers.

A substrate 10 as shown in FIG. 1A, on which an insulation layer 16 was formed, was produced by the same treatment as sample A.

Note that the thickness of the Al layer 14 after insulation layer formation was 20 micrometers.

Sample C

Commercially available pure titanium (purity: 99.5%) and commercially available high-purity aluminum (aluminum purity: 4N) were joined by cold rolling to prepare a two-layer clad material containing an Al layer 14 with a thickness of 30 micrometers and a base 12 (Ti) with a thickness of 50 micrometers.

A substrate 10 as shown in FIG. 1A, on which an insulation layer 16 was formed, was produced by the same treatment as sample A.

Note that the thickness of the Al layer 14 after insulation layer formation was 20 micrometers.

Sample D

A commercially available ferritic stainless steel (SUS430) and high-purity aluminum (aluminum purity: 4N) were joined by cold rolling to prepare a two-layer clad material including an Al layer 14 with a thickness of 80 micrometers and a base 12 (stainless steel) with a thickness of 50 micrometers.

A substrate 10 as shown in FIG. 1A, on which an insulation layer 16 was formed, was produced by the same treatment as sample A except that the electrolytic polishing time was increased.

Note that the thickness of the Al layer 14 after insulation layer formation was 50 micrometers.

Sample E

A substrate 10 as shown in FIG. 1A, on which an insulation layer 16 was formed, was produced by the same treatment as sample A except that the two-layer clad material of sample A (Al layer 30 micrometers, base 50 micrometers) was used, and the electrolytic polishing time was increased.

Note that the thickness of the Al layer 14 after insulation layer formation was 5 micrometers.

Sample F

A substrate 10 as shown in FIG. 1A, on which an insulation layer 16 was formed, was produced by the same treatment as sample A except that the two-layer clad material of sample D (Al layer 80 micrometers, base 50 micrometers) was used.

Note that the thickness of the Al layer 14 after insulation layer formation was 70 micrometers.

Heat Treatment and Evaluation

Samples A to F produced in this way were heat-treated under various conditions.

Heat treatment was performed using a rapid-heating furnace, with a holding temperature of 475 to 600 deg C. and a holding time of 1 to 50 minutes. The heat treatment conditions for each sample are shown in Table 1.

After heat treatment, the thicknesses of the alloy layer 20 and the Al layer 14 were measured for each sample, and substrate warpage and insulation characteristics were evaluated.

Thicknesses of Alloy Layer and Aluminum Layer

A cross-section of each sample was observed, and generation of the alloy layer 20 at the interface between the base 12 and Al layer 14 was evaluated, and the state of decrease in thickness of aluminum was evaluated.

Each sample was sectioned by a diamond cutter, after which figuring was performed by ion polishing using an argon ion beam, and then it was observed by SEM-EDX (scanning electron microscope with energy-dispersive X-ray spectroscope). Because the average electron quantities of the insulation layer 16 (anodized aluminum film), Al layer 14, alloy layer 20 and base (metal base) are different, an image with distinct contrasts is obtained when an SEM-reflected electron image is used.

The area of each layer in the image was measured by image analysis, and the thickness of each layer was determined by dividing it by the length of the field of observation. The observed field magnification was set to 1000 to 10,000 in accordance with the thickness of the alloy layer 20 that had grown.

Substrate Warpage

The front surface of the sample was scanned by a two-dimensional laser displacement meter, and the radius of curvature of the substrate was measured.

Insulation Characteristics

To see the influence of the alloy layer 20 generated at the interface between the base 12 and the Al layer 14 on the insulation characteristics of the substrate 10, the insulation layer 16 was made to run along a jig with a radius of curvature of 80 mm so as to form a convex surface, after which insulation testing was performed after applying bending strain 10 times in each of the two orthogonal directions.

Insulation characteristics measurement was performed by providing a gold electrode with a thickness of 0.2 micrometers and a diameter of 3.5 mm by masked vapor deposition on top of the surface of the insulation layer 16, and applying 200 V of negative polarity voltage to the gold electrode. The value obtained by dividing the leakage current by the gold electrode surface area (9.6 mm²) was used as the leakage current density. This measurement was performed with nine gold electrodes provided on the same substrate, and the average of these was taken as the leakage current density of the substrate. Also, non-uniformity (minimum-maximum) in leakage current density of the nine gold electrodes on each substrate was also evaluated.

Note that the samples in which warpage was seen were measured while flattening by pushing on the ends other than the measured part.

The results are shown in Table 1.

TABLE 1

| | | | | Alloy | | | | |
|---|---|---|---|---|---|---|---|---|
| | | Treatment Conditions | | Layer | Al Layer | Radius of | | Leakage |
| | | Temperature | Time | Thickness | Thickness | Curvature | Leakage Current | Current |
| | Sample | (° C.) | (minutes) | [μm] | [μm] | [cm] | [μA/cm²] | Non-uniformity |
| Working | A | 530 | 10 | 0.01 | 20 | 100 | 0.75 | 0.65-0.83 |
| Example 1 | | | | | | | | |
| Working | A | 600 | 2 | 0.05 | 20 | 100 | 0.71 | 0.62-0.81 |
| Example 2 | | | | | | | | |
| Working | A | 600 | 5 | 5 | 18 | 90 | 0.69 | 0.61-0.75 |
| Example 3 | | | | | | | | |
| Working | A | 600 | 10 | 7 | 17 | 90 | 0.7 | 0.62-0.83 |
| Example 4 | | | | | | | | |
| Working | A | 600 | 15 | 10 | 16 | 70 | 0.72 | 0.63-0.80 |
| Example 5 | | | | | | | | |
| Working | B | 530 | 5 | 8 | 17 | 70 | 0.78 | 0.63-0.90 |
| Example 6 | | | | | | | | |
| Working | C | 600 | 20 | 10 | 16 | 60 | 0.69 | 0.62-0.76 |
| Example 7 | | | | | | | | |
| Working | D | 600 | 15 | 10 | 45 | 50 | 0.72 | 0.62-0.85 |
| Example 8 | | | | | | | | |
| Working | E | 600 | 10 | 7 | 1 | >100 | 0.96 | 0.64-1.48 |
| Example 9 | | | | | | | | |
| Comparative | A | — | — | 0 | >100 | >100 | 4.6 | 0.64-21.0 |
| Example 1 | | | | | | | | |
| Comparative | B | — | — | 0 | >100 | >100 | 2.4 | 0.68-15.6 |
| Example 2 | | | | | | | | |
| Comparative | C | — | — | 0 | >100 | >100 | 3.4 | 0.64-23.6 |
| Example 3 | | | | | | | | |
| Comparative | D | — | — | 0 | >100 | >100 | 10.8 | 0.61-58.5 |
| Example 4 | | | | | | | | |
| Comparative | E | — | — | 0 | >100 | >100 | 1.5 | 0.65-15.3 |
| Example 5 | | | | | | | | |
| Comparative | A | 600 | 20 | 13 | 14 | 70 | All insulation | — |
| Example 6 | | | | | | | destroyed | |
| Comparative | D | 600 | 20 | 13 | 43 | 30 | 12.5 | 9.5-25.5 |
| Example 7 | | | | | | | | |
| Comparative | E | 600 | 15 | 8 | 0.5 | — | All insulation | — |
| Example 8 | | | | | | | destroyed | |
| Comparative | F | 600 | 15 | 10 | 65 | 10 | 25.6 | 8.7-58.5 |
| Example 9 | | | | | | | | |

In the above table, the radius of curvature of comparative example 8 could not be measured because the surface had undulations.

Also, for comparative example 4, the insulation was destroyed in measurement of two of the nine gold electrodes, and in comparative examples 7 and 9, the insulation was destroyed in measurement of four of the nine gold electrodes. For this reason, the average, minimum and maximum values for the gold electrodes in which the insulation was not destroyed were used for their leakage current density and non-uniformity of leakage current density.

Note that in comparative example 8, the alloy layer 20 and insulation layer 16 were in direct contact, and in addition, the radius of curvature could not be measured because the surface of the substrate 10 had undulations.

As shown in Table 1, in the working examples of the present invention, in which the thickness of the alloy layer 20 was 10 micrometers or less, the thickness of the Al layer 14 was at least 1 micrometer and the thickness of the base 12 was 50 micrometers or less, the radius of curvature was at least 50 cm in all cases, and there was a large difference in leakage current density from those that did not undergo heat treatment.

In contrast, in the comparative examples, in which either the thickness of the alloy layer 20 or the thickness of the Al layer 14 was outside the range of the present invention, leakage current was large and non-uniformity in measured values was large. Also, there were substrates in which the insulation layer was destroyed while the voltage was being increased to 200 V. Additionally, in substrates in which the insulation was not destroyed, the radius of curvature was 50 cm or less, and there was visible warpage.

Discussion of Alloy Layer and Interface

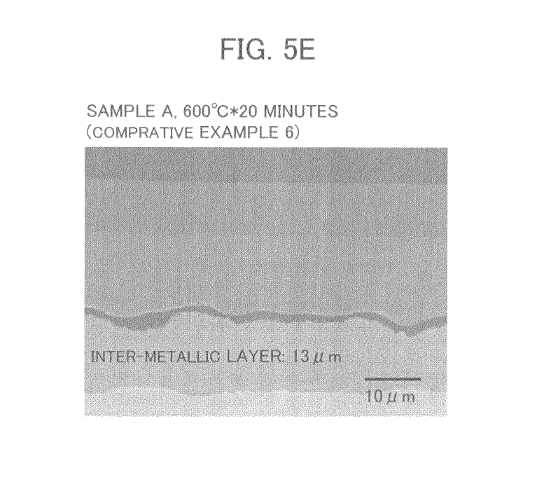

The cross-sections of working examples 2, 3 and 5 and comparative examples 1 and 6, in which sample A was used, are shown in FIG. 4 and FIG. 5. Note that in FIG. 4, A is comparative example 1 (alloy layer (inter-metallic layer) 0 micrometers), B is working example 2 (alloy layer 0.05 micrometers), C is working example 3 (alloy layer 5 micrometers) and D is working example 5 (alloy layer 10 micrometers), and FIG. 5E is comparative example 6 (alloy layer 13 micrometers).

These samples were clad materials obtained by cold rolling after surface cleaning to remove natural oxide film and oils from the bonding surface. In samples that were not heat treated, no alloy film was seen by SEM at 10,000 times magnification.

In contrast, in the examples in which holding at high temperature was performed, an alloy layer 20 was generated at the interface between the base 12 (SUS430 steel) and Al layer 14. Here, in cases where the heat treatment time was short or the temperature was not that high, the alloy layer 20 was generated in the form of islands of maximum thickness 1 micrometer as shown in FIG. 4B, and the average thickness was 0.05 micrometers. On the other hand, in the examples in which heat treatment was at a higher temperature or longer time, it grew in a continuous layer with average thickness of at least 1 micrometer, as shown in the other diagrams.

Note that, as described above, although hills and valleys could be seen at the interface of the alloy layer 20, especially at the interface with the Al layer 14, the alloy layer 20 grew approximately uniformly, and abnormal growth such as in a faceted shape or whisker shape that greatly ate into the aluminum side did not occur.

Also, when the alloy layer 20 was analyzed by EDX, the mole composition of the alloy was Al:Fe:Cr=3:0.8:0.2, and it was estimated to be a layer in which Cr was in solid solution at the Fe sites of the intermetallic compound of the Al₃Fe composition. Note that the mole ratio of Fe:Cr=8:2 substantially matches the mole ratio in SUS430.

When the thickness of the alloy layer 20 was about 5 micrometers, as shown in FIG. 4C, voids estimated to be Kirkendall voids were seen at the interface between the alloy layer 20 and Al layer 14.

When the thickness of the alloy layer 20 was about 10 micrometers, as shown in FIG. 4D, the voids were large, and there were crack-like portions connected to them. However, the crack length stayed at a maximum of 10 micrometers, and when observed at low magnification, the crack region was less than ¼ of the field of vision.

In the case where the alloy layer 20 grew and the thickness exceeded 10 micrometers, as shown in FIG. 5E, cracks were seen along the entire interface in the field of vision.

As shown in the working examples in Table 1, even when the thickness of the alloy layer 20 was 10 micrometers, no substantial abnormalities in leakage current were seen, and they were deemed usable. However, the fact that there were crack-like voids at the interface may be undesirable from the viewpoint of long-term reliability, etc. For this reason, in the present invention, the preferred thickness of the alloy layer 20 is 5 micrometers or less.

When the same observation and analysis were performed for sample B and sample C, respective alloy layers 20 were formed, estimated to be made of an intermetallic compound of Al₃Fe at the aluminum interface with low-carbon steel in sample B after heat treatment, and an intermetallic compound of Al₃Ti in sample C. The condition of the hills and valleys at the interface was the same as in sample A. Additionally, the condition of voids and cracks connected to them versus thickness of the alloy layer 20 was nearly the same as in sample A.

Note that in all samples, due to heat treatment, the thickness of the Al layer 14 decreased due to growth of the alloy layer 20, but the thickness of the base 12 (SUS430, low-carbon steel, Ti) matched that before heat treatment within the margin of error, and was approximately 50 micrometers.

As is clear from the above description of the samples and the description of FIG. 3, in FIGS. 3A and 3B which show the region of heat treatment conditions (holding temperature and holding time) that result in an alloy layer 20 thickness of 10 micrometers and 5 micrometers, a corresponds to sample A which used SUS430 as the base 12, b corresponds to sample B which used low-carbon steel as the base 12, and c corresponds to sample C which used Ti material as the base 12.

As shown by FIG. 3 and the results of heat treatment of the samples, the thickness of the alloy layer 20 increased as the holding time at high temperature was increased. As described above, it is estimated that when the thickness of the alloy layer 20 exceeds 10 micrometers, the interface strength between the alloy layer 20 and aluminum layer 14 decreases, and microcracks tend to occur in the insulation layer 16 (anodized film).

Also, when the results of FIG. 3 and Table 1 are combined, insulation characteristics are maintained and there is no substantial problem with warpage after heat treatment even if the substrates 10 which use various substrates 12 undergo thermal history to the bottom and/or left of the region indicated by the bands in FIG. 3.

This is the same even if semiconductor devices which use the substrates 10 of working examples 1 through 3 undergo the thermal history incurred in the manufacturing processes of the semiconductor circuit portion. For example, in the case of substrate 10 of sample A, even if it undergoes thermal history equivalent to 600 deg C.×15 minutes or 550 deg C.×50 minutes, the thickness of the alloy layer 20 is within 10 micrometers, and it can be used without deformation after heat treatment while maintaining insulation characteristics and flexibility.

### INDUSTRIAL APPLICABILITY

The present invention may be variously employed in the manufacture of semiconductor devices which use an insulating substrate, such as solar cells and organic EL displays.

### REFERENCE SIGNS LIST

10 substrate
12 base
14 Al layer
16 insulation layer
20 alloy layer
30 solar cell
32 lower electrodes
33, 37, 39 spaces
34 light absorbing layer
36 buffer layer
38 upper electrodes
40 thin-film solar cells
42 first conductive member
44 second conductive member
50 alkali supply layer

1. An insulating metal substrate comprising:
a metal base made of steel, iron-based alloy steel or titanium;
an aluminum layer provided on at least one surface of said metal base;
an insulation layer formed by anodizing a front surface of said aluminum layer; and
an alloy layer primarily made of an alloy of a composition expressed by Al₃X (where X is at least one kind of element selected from Fe, Cr, and Ti) and existing in an interface between said metal base and said aluminum layer,
wherein said alloy layer has a thickness of 0.01 to 10 micrometers, and
wherein said aluminum layer has a thickness of 1 micrometer or more and equal to or less than a thickness of said metal base.

2. The insulating metal substrate according to claim 1, wherein said insulation layer is an anodized film of aluminum having a porous structure.

3. The insulating metal substrate according to claim 1, said aluminum layer is provided on said at least one surface of said metal base by pressure bonding an aluminum sheet on said at least one surface of said metal base.

4. The insulating metal substrate according to claim 1, wherein said metal base has a thickness of 10 to 1000 micrometers.

5. The insulating metal substrate according to claim 1, wherein said insulation layer has a thickness of 0.5 to 50 micrometers.

6. A semiconductor device comprising:
The insulating metal substrate according to claim 1; and
semiconductor elements arranged in an array on a front surface of said insulating metal substrate.

7. The semiconductor device according to claim 6, wherein said semiconductor elements are photoelectric conversion elements connected in series.

8. The semiconductor device according to claim 7, wherein each of said photoelectric conversion elements have a light absorbing layer comprising a compound semiconductor having a chalcopyrite-type crystalline structure.

9. The semiconductor device according to claim 8, wherein each of said photoelectric conversion elements have a bottom electrode made of molybdenum, and said compound semiconductor comprises at least one compound semiconductor made of a group Ib element, group IIIb element and group VIb element.

10. The semiconductor device according to claim 9, wherein said group Ib element comprises copper and/or silver, said group IIIb element comprises at least one element selected from the group consisting of aluminum, gallium and indium, and said group VIb element comprises at least one element selected from the group consisting of sulfur, selenium and tellurium.
